(19) United States
(12) Patent Application Publication
(10) Pub. No.: US 2016/0276358 A1
(43) Pub. Date: Sep. 22, 2016

(54) SEMICONDUCTOR DEVICE AND METHOD FOR MANUFACTURING THE SAME

(71) Applicant: Tang ZONG, Hengyang (CN)

(72) Inventor: Di Li, Zhuhai (CN)

(21) Appl. No.: 15/036,299

(22) PCT Filed: Nov. 18, 2014
(86) PCT No.: PCT/CN2014/091349

§ 371 Date: May 12, 2016

(30) Foreign Application Priority Data
Nov. 18, 2013 (CN) 201310581642.0

(51) Int. Cl. H01L 27/115; H01L 21/768; H01L 29/66

(52) U.S. Cl. CPC H01L 27/11556; H01L 27/11582; H01L 29/66666; H01L 21/76879

(57) ABSTRACT

The present invention discloses a semiconductor device and a method for manufacturing the same, and the semiconductor device includes: a first area in which a plurality of device elements are stacked, wherein adjacent ones of the plurality of device elements are spaced by an interlayer insulation layer, and each of the device elements includes a corresponding gate conductor; and a second area adjacent to the first area, wherein the interlayer insulation layer and the gate conductors extend from the first area to the second area, and there are electrically conductive vias in the second area through which the gate conductors and connected with wires, wherein there are also support posts in the second area to support the interlayer insulation layer and the gate conductors. The support posts provides a mechanical support for the floating layers in the process of manufacturing and also supports the gate conductors in the resulting device to thereby improve the yield ratio and reliability of the semiconductor device.

### CROSS-REFERENCE TO RELATED APPLICATION

This application claims the benefit of Chinese Patent Application No. 201310581642.0, filed on Nov. 18, 2013, which is incorporated herein by reference in its entirety.

### BACKGROUND OF THE DISCLOSURE

1. Field of the Invention

The present invention relates to the field of semiconductors and more particularly to a semiconductor device in a three-dimension structure and a method for manufacturing the same.

2. Background of the Invention

In recent years, semiconductor devices in a three-dimension structure have gained widespread attention because the integrity can be doubled, an area occupied by a chip can be decreased and a cost can be lowered. Particularly in the field of memories, a progress of processes of semiconductor manufacturing has come with a decreasing feature size of the semiconductor devices so that it becomes increasingly difficult to improve the density of storage by improving the processes of semiconductor manufacturing. A memory in a three-dimension structure has become crucial to improve the density of storage.

Planar semiconductor devices can be staked at a plurality of layers, and insulation layers can be arranged and interconnections can be provided between the adjacent layers to implement a simple three-dimension structure. The density of storage in such a three-dimension memory can be improved in proportion to the number of layers. Alternatively, memory cells per se can be further translated from planar devices into vertical devices to thereby lower the area occupied by a chip of each memory cell so as to further improve the density of storage in the memory.

NAND and NOR are two general nonvolatile flash-memory technologies at present in the market. An operation of writing to a flash memory can only be performed on an empty or erased cell. It is easy to perform an operation of erasing the NAND flash-memory, whereas the NOR flash-memory has to be erased only if zeros have been written to all the bits in a target block. A smaller memory cell can be embodied in the NAND structure to thereby achieve a higher density of storage. The NAND flash-memory and the NOR flash-memory in a three-dimension structure have been disclosed.

It shall be noted that in the memory in the three-dimension structure, a contact area, in which vertical interconnections, leading-out word lines, etc., are arranged is further arranged on the periphery of an array of memory cells. The contact area, in which there are via holes, interlayer dielectrics, etc., is more complex in structure than the area of the array of memory cells. As a result, additional impurities and electrical and mechanical defects may be introduced to the contact area so that the array of memory cells can not operate normally.

It is still desirable to further improve the reliability of the semiconductor device in the three-dimension structure.

### SUMMARY OF THE INVENTION

An object of the invention is to provide a highly reliable three-dimension semiconductor device and a method for manufacturing the same.

According to an aspect of the invention, there is provided a semiconductor device including: a first area in which a plurality of device elements are stacked, wherein adjacent ones of the plurality of device elements are spaced by an interlayer insulation layer, and each of the device elements includes a corresponding gate conductor; and a second area adjacent to the first area, wherein the interlayer insulation layer and the gate conductors extend from the first area to the second area, and there are electrically conductive vias in the second area through which the gate conductors and connected with wires, wherein there are also support posts in the second area to support the interlayer insulation layer and the gate conductors.

Preferably the plurality of device elements include common vertical channels.

Further preferably the plurality of device elements further include common core insulation layers surrounded by the vertical channels.

Preferably the support posts include the vertical channels and the core insulation layers.

Preferably the support posts are made of one of amorphous silicon and poly-silicon.

Further preferably the semiconductor device further includes a semiconductor substrate, wherein the support posts are made of poly-silicon, and the bottoms of the support post belong to the same crystal domain as the semiconductor substrate.

Preferably the distance between adjacent ones of the support posts is shorter than 100 times the thickness of the interlayer insulation layers.

Preferably when the thickness of the interlayer insulation layers is smaller than 50 nanometers, the distance between adjacent ones of the support posts is smaller than or equal to 5 micrometers.

Preferably the semiconductor device further includes a semiconductor substrate into which the support posts are at least partially embedded.

Preferably the plurality of device elements are stacked at a plurality of layers, the plurality of device elements at each of the layers are arranged in rows and columns, and the device elements in the same column include common gate conductors, whereas the gate conductors of adjacent columns of device elements are spaced by another insulation layer.

Preferably in the second area, the gate conductors of the plurality of device elements are shaped stepwise, and the gate conductor at each of the layers is a level of step.

Preferably the semiconductor device is an NAND memory, and at least some of the plurality of device elements form real strings of memory cells, whereas at least some others of the plurality of device elements form dummy strings of memory cells, and the support posts are dummy strings of memory cells.

According to another aspect of the invention, there is provided a method for manufacturing a semiconductor device including a first area in which a plurality of device elements are stacked, and a second area in which there are electrically conductive vias for contact with the outside, the method including: forming a stack of a plurality of scarification layers and a plurality of interlayer insulation layers alternately stacked; forming openings through the respective layers in the stack of the layers; forming vertical vias in openings in the first area; forming support posts in openings in the second area; removing the plurality of scarification layers so that the plurality of interlayer insulation layers float and are supported by the vertical vias and the support posts, and a part of the surfaces of the vertical vias are exposed; forming an interlayer dielectric layer on the part of the surfaces of the vertical vias; and forming gate conductors between adjacent ones of the interlayer insulation layers so that the gate conductors and the vertical vias are spaced by the interlayer dielectric layer.

Preferably the vertical vias are a conformal layer in the openings in the first area, and the method further includes: forming core insulation layers in the remaining spaces of the openings in the first area.

Preferably the support posts are formed at the same time as the vertical vias so that the support posts are made in the same structure and of the same material as the vertical vias.

Preferably the support posts are formed separately from the vertical vias and made in the same and/or different structures and of the same and/or different materials as the vertical vias.

Preferably after the gate conductors are formed, the method further includes: etching for a plurality of times to expose downward the gate conductors at the respective layers in the contact area.

Preferably etching is performed each of the plurality of times to shield completely all the overlying gate conductors and to expose a part of the gate conductors at the immediately underlying layers.

With the method for manufacturing a semiconductor device according to the invention, the support posts provide a sufficient mechanical support for the floating layers in the process of manufacturing to thereby improve the yield ratio of the semiconductor device. With the semiconductor device according to the invention, the support posts support the gate conductors in the resulting semiconductor device to thereby improve the reliability of the semiconductor device.

### BRIEF DESCRIPTION OF THE DRAWINGS

The foregoing and other objects, features and advantages of the invention will become more apparent from the following description of embodiments of the invention, where in the drawings:

FIG. 1a and FIG. 1b illustrate a perspective view and a top view of a semiconductor device according to an embodiment of the invention respectively;

FIG. 2 to FIG. 11 illustrate sectional views in respective stages of a method for manufacturing a semiconductor device according to an embodiment of the invention respectively, where FIG. 2a to FIG. 11a illustrate vertical sectional views in a direction, FIG. 2b to FIG. 11b illustrate vertical sectional views in another direction, and FIG. 9c illustrates a vertical sectional view of a variant in the same direction as FIG. 9b;

FIG. 12 illustrates a sectional view in a part of stages of a method for manufacturing a semiconductor device according to another embodiment of the invention, where FIG. 12a illustrates a vertical sectional view in a direction, and FIG. 12b illustrates a vertical sectional view in another direction;

FIG. 13 illustrates a top view of a layout of support posts in a contact area of a semiconductor device according to an embodiment of the invention; and

FIG. 14 illustrates a top view of a layout of support posts in a contact area of a semiconductor device according to another embodiment of the invention.

### DETAILED DESCRIPTION OF THE INVENTION

The invention will be described below in further details with reference to the drawings. Like elements are denoted by like reference numerals throughout the drawings. For the sake of clarity, respective components in the drawings have not been drawn to scale. Moreover some well-known components may not have been illustrated. For the sake of conciseness, a semiconductor structure as a result of several steps can be described in the same figure.

It shall be appreciated that in a description of the structure of a device, when a layer or an area is referred to as “on” or “above” another layer or another area, the layer or the area can be directly on the other layer or the other area, or there can be an intermediate layer or area between the layer or the area and the other layer or the other area. Moreover if the device is inverted, then the layer or the area will be “below” or “under” the other layer or the other area.

If the layer or the area is described as directly on the other layer or the other area, then it will be described in this context as “directly on” or “on and adjacent to” the other layer or the other area.

In this application, the term “semiconductor structure” generally refers to the entire semiconductor structure as a result of respective steps in which a semiconductor device is manufactured, including all the layers or areas formed in the semiconductor structure. Numerous particular details of the invention will be described below, e.g., the structure, the material, the size, the process and the technology of the device, so as to understand the invention more clearly. However those skilled in the art can appreciate that the invention can be embodied without these particular details.

Respective components of the semiconductor device can be made of materials well known to those skilled in the art unless otherwise indicated below. For example, the semiconductor materials include an III-V family semiconductor, e.g., GaAs, InP, GaN, SiC, etc., and an IV family semiconductor, e.g., Si, Ge, etc. A gate conductor can be made of various electrically conductive materials, e.g., a metal layer, a doped poly-silicon layer, a stacked gate conductor including a metal layer and a doped poly-silicon layer, or another electrically conductive material, e.g., TaC, TiN, TaSiN, HfSiN, TiSiN, TiCN, TaAlC, TiAlN, TaN, PtSix, Ni3Si, Pt, Ru, W and a combination thereof. A gate dielectric can be made of SiO2 or a material with a higher dielectric constant than SiO2, e.g., oxide, nitride, oxynitride, silicate, aluminate, titanate, etc. Moreover the gate dielectric can be made of both a material well-known to those skilled in the art and a material to be developed later for the gate dielectric.

The invention can be embodied in various forms, some examples of which will be described below.

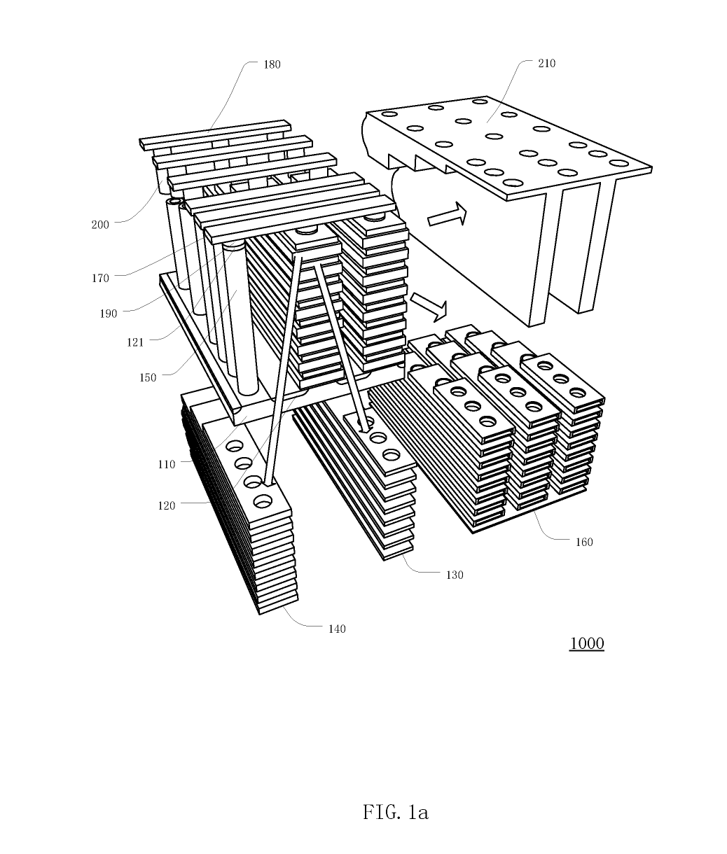

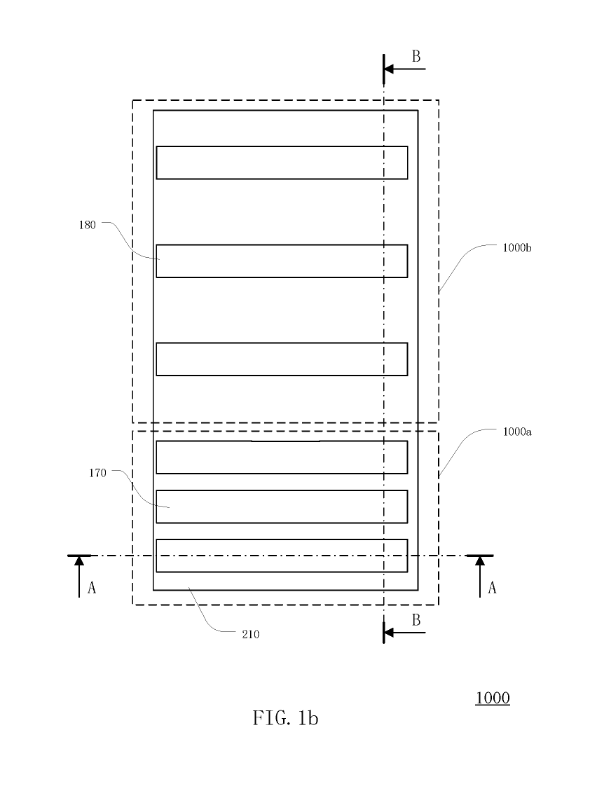

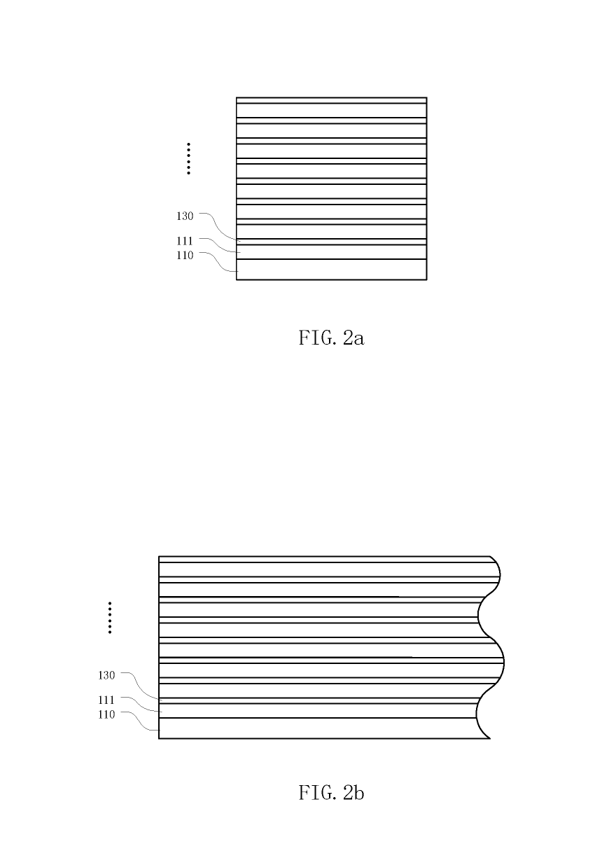

Referring to FIG. 1a and FIG. 1b, there are illustrated schematic diagrams of a semiconductor device according to an embodiment of the invention, where FIG. 1a illustrates a perspective view of the semiconductor device, and FIG. 1b illustrates a top view of the semiconductor device. FIG. 1b further illustrates locations at which subsequent vertical sectional views are taken, where FIG. 2a to FIG. 12a are vertical sectional views taken through the line A-A passing a row of device elements, and FIG. 2b to FIG. 12b and FIG. 9c are vertical sectional views taken through the line B-B passing a column of device elements. Moreover the wavy lines in FIG. 2b to FIG. 12b and FIG. 9c represent only a part of a corresponding layer.

As illustrated in FIG. 1a and FIG. 1, the semiconductor device 1000 includes device elements at 8 layers at each of which there are 3 rows by 3 columns of device elements totaling to 72 device elements. In an example, the semiconductor device 1000 is an NAND memory, where device elements at the top are string selection transistors, device elements at the bottom are device ground selection transistors, and device elements at the 6 middle layers are memory cells, totaling to 54 memory cells. 6 memory cells stacked vertically per group constitute a string of memory cells totaling 9 strings of memory cells. Adjacent columns of device elements are spaced by an interlayer insulation layer 210. The semiconductor device 1000 can include more or less layers, rows, columns and device elements. For the sake of clarity, FIG. 1a illustrates interlayer insulation layers 130 and gate conductors 140 of the leftmost column of device elements, and a middle dielectric layer 160 and the interlayer insulation layer 210 common to all the device elements, in an exploded view.

Particularly the semiconductor device 1000 includes a semiconductor substrate 110. The semiconductor substrate 110 is a silicon substrate, for example. In an example, a N-type or P-type first doping area 120 is formed in the semiconductor substrate 110. In the case that the semiconductor device 1000 is an NAND memory, the first doping area 120 is source areas of the ground selection transistors.

The interlayer insulation layers 130 are located above the semiconductor substrate 110 to space the gate conductors 140 at different layers. A plurality of openings are formed in the interlayer insulation layers 130 and the gate conductors 140 to accommodate vertical channels 150, which are columnar, respectively. The vertical channels 150 are surface semiconductor layers on core insulation layers, for example. In an example, the vertical channels 150 are doped at the top to form a second doping area 121 of the same type of conductivity as the first doping area 120. The middle dielectric layer 160 is located between the vertical channels 150 and the gate conductors 140. In the case that the semiconductor device 1000 is an NAND memory, the second doping area 121 is drain areas of the string selection transistors, and the middle dielectric layer 160 is a stack of layers including a tunneling dielectric layer, a charge capturing layer and a barrier layer to store charges representing a value of data, and the middle dielectric layer 160 is also a gate dielectric layer of the string selection transistors and the ground selection transistors. Although the middle dielectric layer 160 conformably covers the surface of the interlayer insulation layer 130 and the exposed surfaces of the vertical channels 150 as illustrated, this may not be necessary. In an alternative embodiment, the middle dielectric layer 160 can be localized between the gate conductors 140 and the vertical channels 150, for example, without covering the interlayer insulation layer 130.

In the array of cells area 1000a (as illustrated in FIG. 1b), the second doping area 121 is connected with a first group of wires 170 through electrically conductive vias (190). The electrically conductive vias 190 are formed in via holes in the interlayer insulation layer 210, for example. In a contact area 1000b (as illustrated in FIG. 1b), the vertical channels 150 are not connected with any external circuit, or alternatively the gate conductor 140 at each layer is connected with one of a second group of wires 180 through an electrically conductive via 200 respectively. The electrically conductive vias 200 are formed in the via holes in the interlayer insulation layer 210, for example. Thus the vertical channels 150 and the core insulation layers 151 in the contact area 1000b are merely support posts. It shall be noted that for the sake of clarity, FIG. 1a and FIG. 1b illustrate only the wires connected to the gate conductors 140 of the device elements at the upper three layers but not the wires connected to the gate conductors 140 of the device elements at the lower three layers.

In the case that the semiconductor device 1000 is an NAND memory, the first group of wires 170 is bit lines BL of the memory, and the second group of wires 180 includes a string selection line SSL connected with the gate conductor 140 of the topmost string selection transistor, a ground selection line GSL connected with the gate conductor 140 of the bottommost ground transistor and 6 word lines WL respectively connected with the gate conductors 140 of the memory cells. In the array of cells area 1000a, the gate conductors 140, the middle dielectric layer 160 and the vertical channels 150 together form the strings of memory cells and the selection transistors, and in the contact area 1000b, the gate conductors 140, the middle dielectric layer 160 and the vertical channels 150 form dummy memory cells and dummy selection transistors which are support posts. In an alternative embodiment, separate support posts can be used in the place of the vertical channels 150 and the core insulation layers 151 in the contact area 1000b.

Respective stages in a method for manufacturing a semiconductor device according to an embodiment of the invention will be described with reference to FIG. 2 to FIG. 11.

As illustrated in FIG. 2a and FIG. 2b, a scarification layer 111 is formed on a semiconductor substrate 110, and then an interlayer insulation layer 130 is formed, and furthermore the steps of forming the scarification layer 111 and the interlayer insulation layer 130 are repeated to thereby form the stack of the scarification layers 111 and the interlayer insulation layers 130. The scarification layers 111 can be made of a material removed selectively to the semiconductor substrate 110 and the interlayer insulation layers 130. For example, the semiconductor substrate 110 is made of Si, the interlayer insulation layers 130 are made of SiO2, and the scarification layers 111 are made of SiGe, so that the scarification layers 111 can be subsequently removed selectively to the semiconductor substrate 110 and the interlayer insulation layers 13.

In order to form device elements at 8 layers, the stack of the layers shall include at least 8 scarification layers 111. The scarification layers 111 and the interlayer insulation layers 13 can be formed in a well-known deposition process, e.g., Electric Beam Melting (EBM), Chemical Vapor Deposition (CVD), Atomic Layer Deposition (ALD), sputtering, etc.

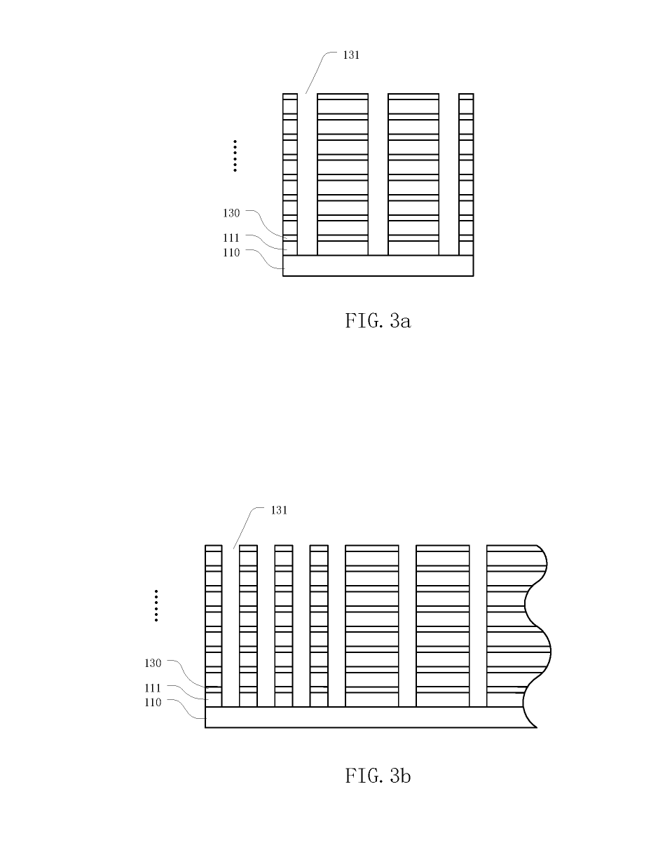

Furthermore, for example, a photo-resist mask is formed on the surface of the semiconductor structure and then etched to pattern the stack of the scarification layers 111 and the interlayer insulation layers 130 to form a plurality of openings 131. Etching can be dry etching, e.g., ion mill etching, plasma etching, reactive ion etching, laser ablation, etc., or selective wet etching using etchant solution, where the photo-resist mask is etched from openings therein down all the scarification layers 111 and the interlayer insulation layers 130 until the surface of the semiconductor substrate 110. The etched photo-resist mask is removed by being dissolved in solvent or ashed as illustrated in FIG. 3a and FIG. 3b.

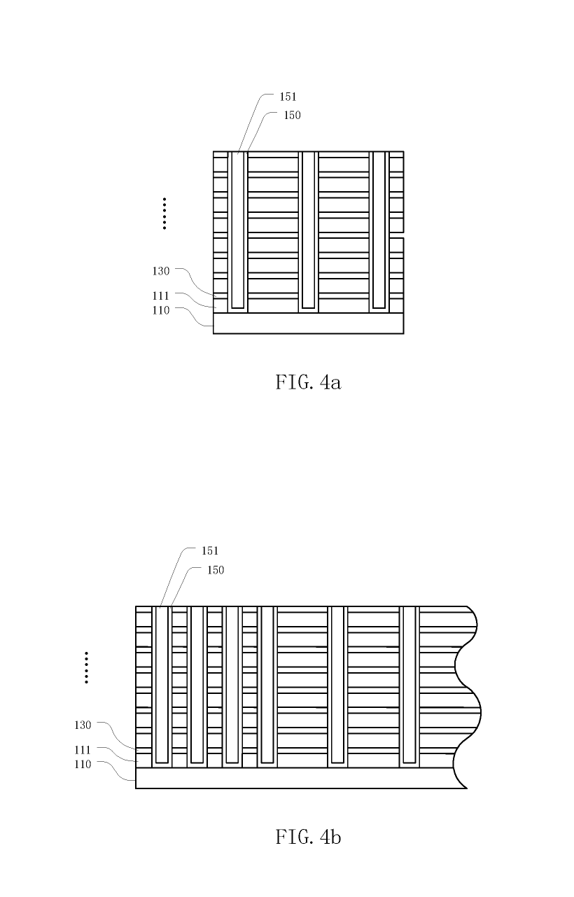

Furthermore in the well-known deposition process above, vertical channels 150 are formed on the sidewalls and the bottoms of the openings 131, and furthermore core insulation layers 151 are deposited to fill the openings completely as illustrated in FIG. 4a and FIG. 4b. The vertical channels 150 can be formed by forming conformal layers on the sidewalls and the bottoms of the openings 131 in the well-known deposition process above so that the openings are formed in the remaining spaces of the openings 131 to accommodate the core insulation layers 151 or alternatively by filling the openings 131 completely in the well-known deposition process above and then etching the photo-resist mask to form the openings to accommodate the core insulation layers 151. For example, the vertical channels 150 are made of Si, and the core insulation layers 151 are made of SiO2.

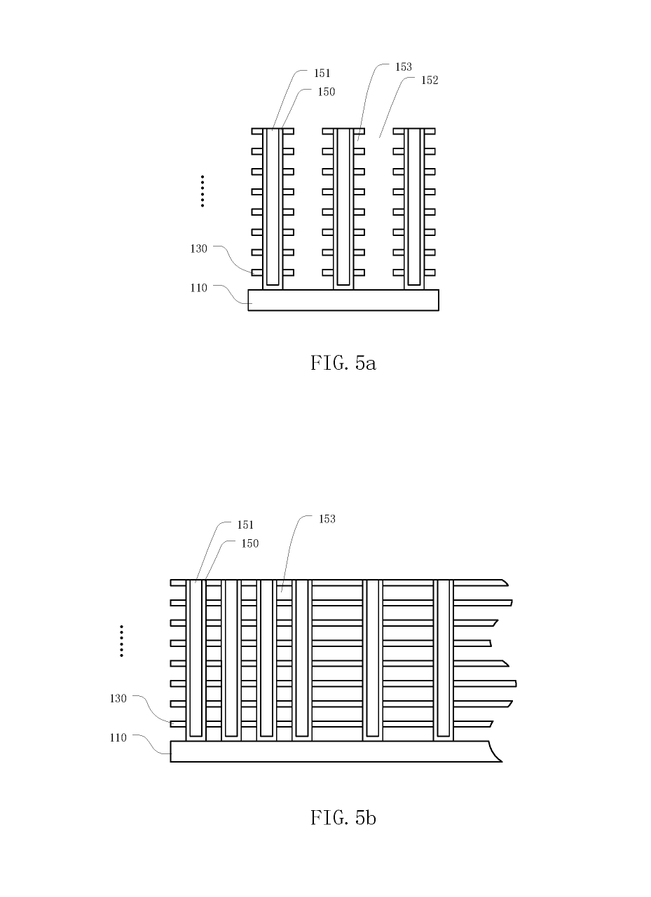

Furthermore, for example, a photo-resist mask is formed on the surface of the semiconductor structure, and then the stack of the scarification layers 111 and the interlayer insulation layers 130 is patterned in the etching process above to form trenches 152 to space adjacent columns of device elements in the resulting semiconductor device 1000. Then the scarification layers 111 are further completely removed selectively to the vertical channels 150, the interlayer insulation layers 152 and the semiconductor substrate 110 through the trenches 152 in a selective etching process to form openings 153 extending traverse to the vertical channels 150. The etched photo-resist mask is removed by being dissolved in solvent or ashed. The trenches 152 and the openings 153 together expose a part of the surfaces of the vertical channels 150 and the interlayer insulation layers 130 as illustrated in FIG. 5a and FIG. 5b.

In the step above, the interlayer insulation layers 130 float over the underlying layers after the scarification layers 111 are removed. In the array of cells area 1000a, the columnar vertical channels 150 and the core insulation layers 151 together support mechanically the interlayer insulation layers 130. Unlike the prior art, in the contact area 1000b, the columnar vertical channels 150 and the core insulation layers 151 together support mechanically the interlayer insulation layers 130 as well.

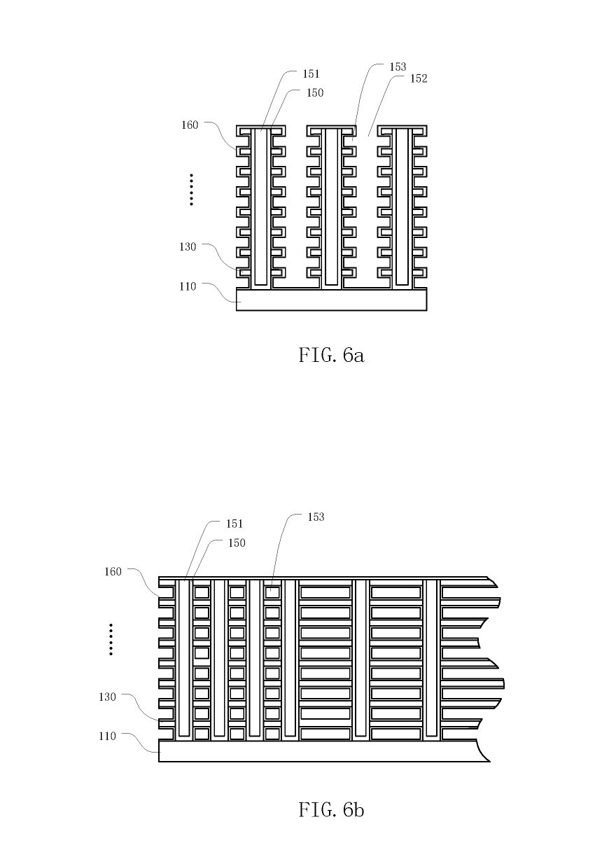

Furthermore a conformal middle dielectric layer 160 is formed on the exposed surfaces of the vertical channels 150 and the interlayer insulation layers 130 through the trenches 152 and the openings 153 in an isotropic deposition process as illustrated in FIG. 6a and FIG. 6b. In the meanwhile, the middle dielectric layer 160 covers the top surface of the semiconductor structure. Although the middle dielectric layer 160 is illustrated as a single layer in the figure, the middle dielectric layer 160 can be a conformal stack of layers deposited for a plurality of times in reality. As described above, in the case that the semiconductor device 1000 is an NAND memory, the middle dielectric layer 160 is a stack of layers including a tunneling dielectric layer, a charge capturing layer and a barrier layer to store charges representing a value of data, and the middle dielectric layer 160 is also a gate dielectric layer of string selection transistors and ground selection transistors.

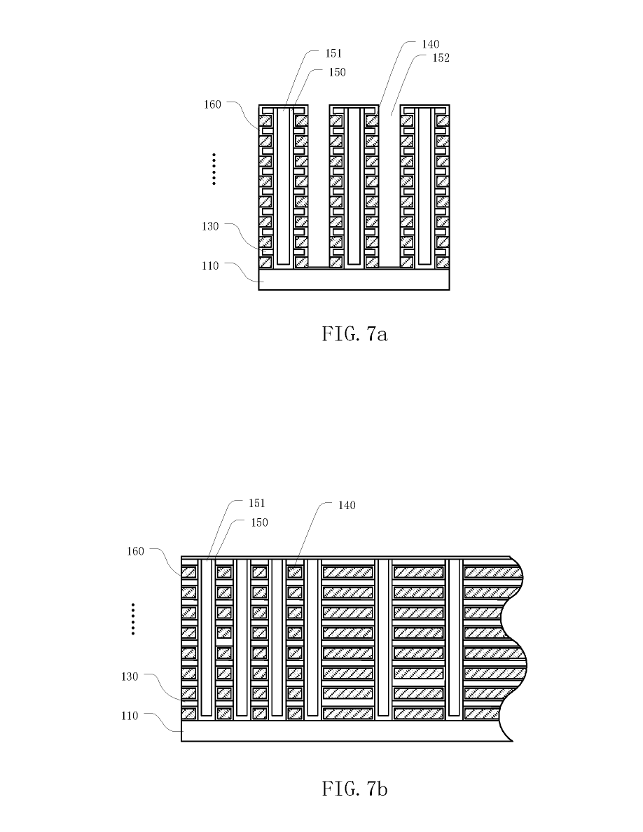

Furthermore gate conductors 140 are formed through the trenches 152 in an isotropic deposition process to fill the openings 153. The gate conductors 140 can be formed by forming a conformal layer on the sidewalls and the bottoms of the openings 153 in the well-known deposition process above so that the thickness of the conformal layer is sufficient to fill the openings 153 but not sufficient to fill the trenches 152 or alternatively by filling completely the openings 153 and the trenches 152 in the isotropic deposition process above and then etching in an anisotropic etching process to reform the trenches 152 as illustrated in FIG. 7a and FIG. 7b.

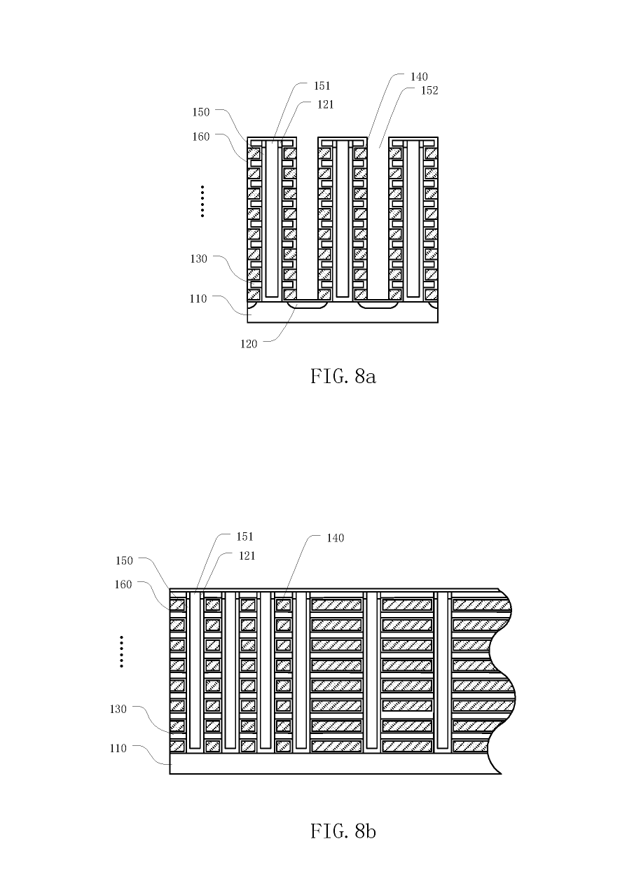

Furthermore ions are injected through the trenches 152 to form a first N-type (using an N-type dopant, e.g., P, As, etc.) or P-type (using a P-type dopant, e.g., B, etc.) first doping area 120 in the semiconductor substrate 110. In the meanwhile the dopant also penetrates the top surface of the middle dielectric layer 160 to form a second doping area 121 on the areas at the top of the vertical channel 150 of the same type of conductivity as the first doping area 120 as illustrated in FIG. 8a and FIG. 8b. In the case that the semiconductor device 1000 is an NAND memory, the first doping area 120 is active areas of the ground selection transistors, and the second doping area 121 is drain areas of the string selection transistors.

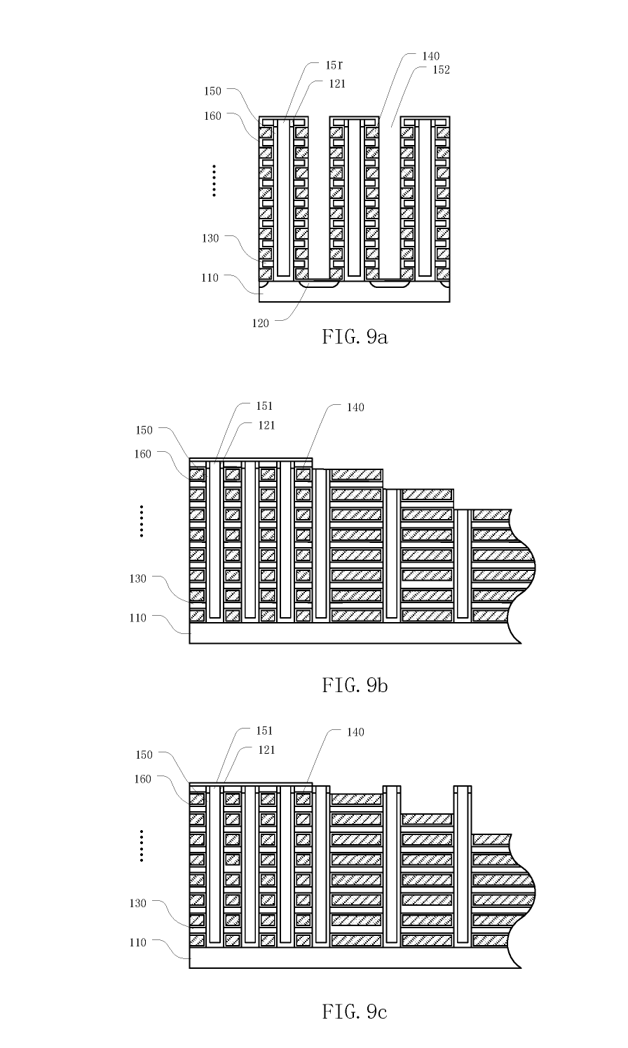

Furthermore, for example, a photo-resist mask is formed on the surface of the semiconductor structure and then etched in the contact area 1000b, for example, by removing selectively such a part of the topmost one of the interlayer insulation layers 130 that is not shielded by the photo-resist mask and a corresponding part of the interlayer dielectric layer 160 to thereby expose the underlying gate conductor 140. The etched photo-resist mask is removed by being dissolved in solvent or ashed. Then the steps of forming, selectively etching and removing the photo-resist mask are repeated to expose downward the gate conductors 140 at the respective layers in the contact area 1000b as illustrated in FIG. 9a and FIG. 9b. Etching is performed each time to shield completely all the overlying gate conductors 140 and to expose a part of the gate conductors 140 at the immediately underlying layers so that the gate conductors 140 at all the layers appear stepwise, where the gate conductor 140 at each layer is a level of step. In this etching step, the gate conductors 140 at the respective layers are exposed but also the parts of the vertical channels 150 and the core insulation layers 151 above the corresponding gate conductors 140 are etched and removed.

FIG. 9c illustrates a vertical sectional view of a variant in the same direction as FIG. 9b, where the parts of the vertical channels 150 and the core insulation layers 151 above the corresponding gate conductors 140 are not removed. As compared with the variant illustrated in FIG. 9c, the embodiment illustrated in FIG. 9b is preferred because the protruding parts of the vertical channels 150 and the insulation layers 151 are removed to thereby facilitate an improved ratio of covering a conductor layer and/or an interlayer insulation layer to be deposited.

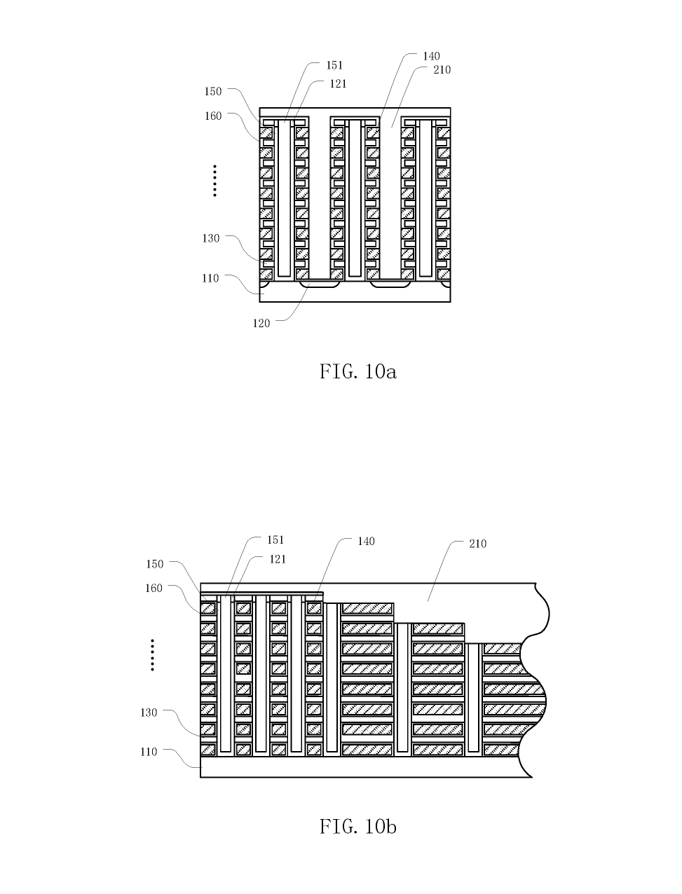

Then an interlayer insulation layer 210 is formed on the surface of the semiconductor structure in the well-known deposition process above and further planarized mechanically (e.g., through chemical mechanical polishing) to obtain a planar surface thereof as illustrated in FIG. 10a and FIG. 10b. The interlayer insulation layer 210 fills the trenches 152 and spaces adjacent columns of device elements in the resulting semiconductor device 1000. The interlayer insulation layer 210 covers the top surface of the middle dielectric layer 160 in the array of cells area 1000a. The interlayer insulation layer 210 covers the exposed surfaces of the gate conductors 140 shaped stepwise in the contact area 1000b.

Furthermore, for example, a photo-resist mask is formed on the surface of the semiconductor structure, and the interlayer insulation layer 210 and the middle dielectric layer 160 are patterned in the array of cells area 1000a in the etching process above to form via openings in the second doping area 121, and the insulation layer 201 is patterned in the contact area 1000b to form via openings to the gate conductors 140.

Then a conductor layer is formed in the well-known deposition process above to fill at least the via openings. With the interlayer insulation layer 210 being a stop layer, the conductor layer is planarized mechanically (e.g., through chemical mechanical polishing) to remove a part of the conductor layers outside the via openings so as to form electrically conductive vias 190 in the array of cells area 1000a and electrically conductive vias 200 in the contact area 1000b.

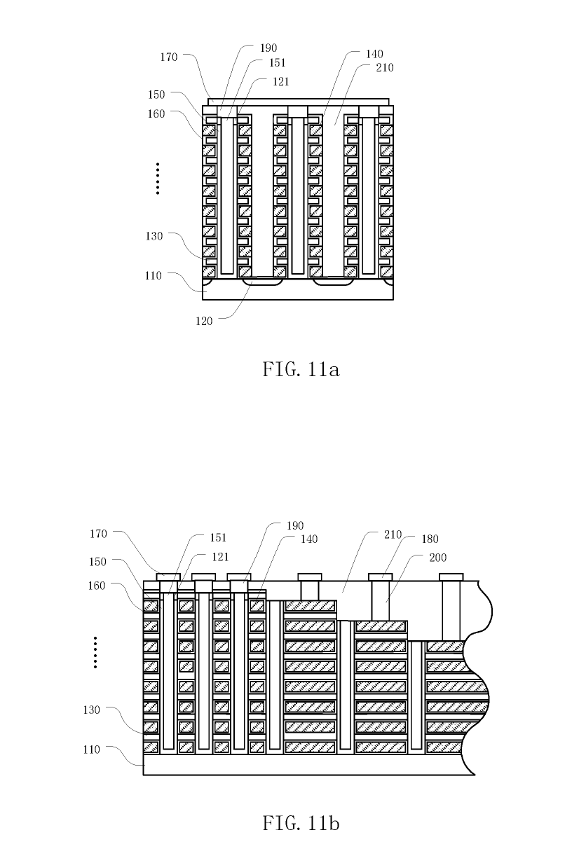

Then a conductor layer is formed again on the interlayer insulation layer 210 in the well-known deposition process above and patterned into a first group of wires 170 and a second group of wires 180 as illustrated in FIG. 11a and FIG. 11b. The first group of wires 170 is located in the array of cells area 1000a in contact with the electrically conductive vias 190. The second group of wires 180 is located in the contact area 1000b in contact with the electrically conductive vias 200. As described above, in the case that the semiconductor device 1000 is an NAND memory, the first group of wires 170 is bit lines BL of the memory, and the second group of wires 180 includes a string selection line SSL connected with the gate conductor 140 of the topmost string selection transistor, a ground selection line GSL connected with the gate conductor 140 of the bottommost ground transistor and 6 word lines WL respectively connected with the gate conductors 140 of the memory cells.

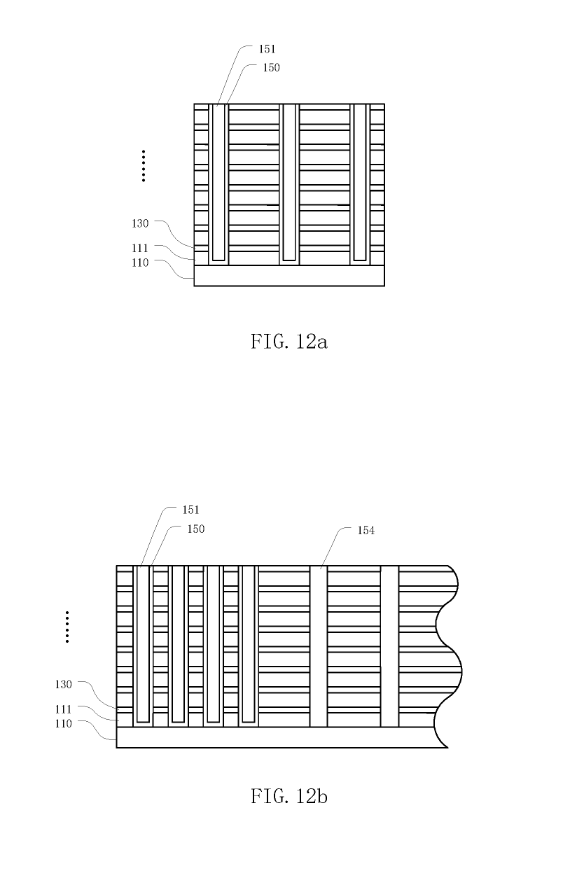

A part of stages of a method for manufacturing a semiconductor device according to another embodiment of the invention will be described with reference to FIG. 12.

After the steps illustrated in FIG. 2 to FIG. 3, instead of the step illustrated in FIG. 4, columnar vertical channels 150 and core insulation layers 151 are formed in the openings 131 in the array of cells area 1000a, and additional support posts 154 are formed in the openings 131 in the contact area 1000b, as illustrated in FIG. 12. Subsequent steps in this method are the same as the steps illustrated in FIG. 5 to FIG. 11.

In the step illustrated in FIG. 4, the vertical channels 150 and the core insulation layers 151 are support posts. Unlike this, separate support posts 154 are formed in the step illustrated in FIG. 12 so that an appropriate material and layout can be selected for the support posts 154 to accommodate a mechanical support desirable to the contact area 1000b.

In a preferred embodiment, in order to improve the adhesion between the support posts 154 and the semiconductor substrate 110, amorphous silicon can be firstly deposited to fill the openings 131 and then annealed into poly-silicon. The lower areas of the support posts 154 are grown epitaxially at least using the semiconductor substrate as a crystal seed to thereby form a crystal domain similar to the crystal structure of the substrate. Since the lower areas of the support posts 154 belong to the same crystal domain as the semiconductor substrate 110, the adhesion between the support posts 154 and the semiconductor substrate 110 can be enhanced to thereby make the support posts 154 more robust in structure

In another preferred embodiment, in order to improve the adhesion between the support posts 154 and the semiconductor substrate 110, the openings 131 can be formed through etching so that the openings 131 extend at the bottom into the semiconductor substrate 110 to form grooves. The support posts 154 to be formed will be partially embedded into the semiconductor substrate 110 to thereby further enhance the stability of the support posts.

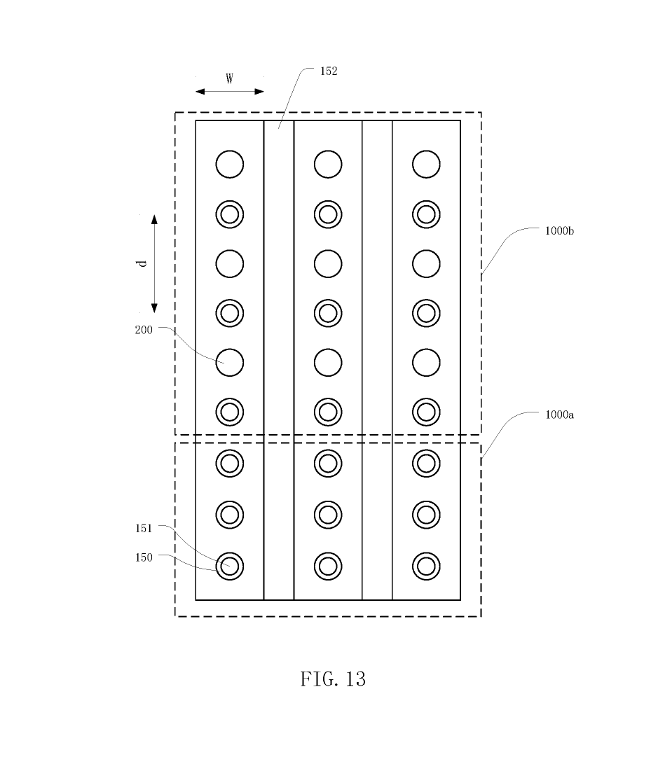

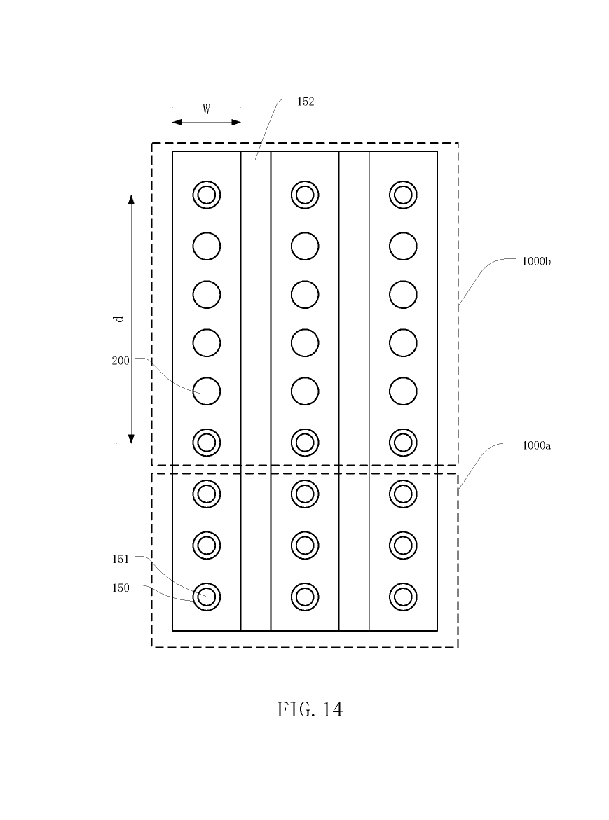

FIG. 13 and FIG. 14 illustrate a layout of support posts in the contact area of the semiconductor device according to the invention. For the sake of clarity, the interlayer insulation layers 130, the gate conductors 140, the middle dielectric layer 160, the first doping area 120, the electrically conductive vias 190, the first group of wires 170 and the second group of wires 180 of the semiconductor device 1000 are not illustrated in the figure.

In the array of cells area 1000a, the vertical channels 150 and the core insulation layers 151 are common to a plurality of vertically stacked device elements, provide the plurality of device elements with channel areas connected in series in the stacking direction and are connected with the first set of wires 170, and in the contact area 1000b, the vertical channels 150 and the core insulation layers 151 are only support posts but not electrically connected with any external circuit. In the semiconductor device 1000 is an NAND memory, in the array of cells area 1000a, the gate conductors 140, the middle dielectric layer 160 and the vertical channels 150 together form the strings of memory cells and the selection transistors, and in the contact area 1000b, the gate conductors 140, the middle dielectric layer 160 and the vertical channels 150 form dummy memory cells and dummy selection transistors. As described above, in an alternative embodiment, separate support posts can be used in the place of the vertical channels 150 and the core insulation layers 151 in the contact area 1000b.

Moreover in the array of cells area 1000a, the device elements are arranged in rows and columns, and the adjacent columns of device elements are spaced by the trenches 152. In the contact area 1000b, there are the support posts composed of the vertical channels 150 and the core insulation layers 151 and also electrically conductive vias 200 extending upward from the gate conductors to be electrically connected with the second group of wires 180. In order to minimize the area occupied by the chips of the device elements, there is a column width W of typically below 200 nanometers. This in a preferred embodiment, the electrically conductive vias 200 are arranged in the same column as the vertical channels 50 and the core insulation layers 151 in the contact area 1000b to thereby facilitate a decreased column so as to lower the area occupied by the chip and improve the density of devices, where d represents the distance between adjacent support posts (i.e., the vertical channels 150 and the chip insulation layers 151 in the contact area 1000b), as illustrated in FIG. 13 and FIG. 14.

In the layout illustrated in FIG. 13, there is an electrically conductive via 200 arranged between adjacent support posts. In the layout illustrated in FIG. 14, there are 4 electrically conductive channels 200 arranged between adjacent support posts. Apparently any number more than one of electrically conductive channels 200 can be arranged between adjacent support posts.

The layout of the support posts shall provide a sufficient mechanical support for a floating layer (e.g., an interlayer insulation layer 130) occurring in the process of manufacturing the semiconductor device 1000 and also support the gate conductors in the resulting device.

Preferably the number of electrically conductive vias 200 between adjacent support posts is smaller than or equal to 10.

Preferably the distance between support posts varies with the thickness of the floating layer. In the case that the floating layer is an interlayer insulation layer 130, if the thickness of the interlayer insulation layer 130 is decreased, then the mechanical strength of the layer degrades, so it is necessary to shorten the distance between support posts.

Further preferably the distance between support posts needs to be shorter than 100 times the thickness of the interlayer insulation layer 130. When the thickness of the interlayer insulation layer 130 is smaller than 50 nanometers, preferably the distance d between adjacent support posts is smaller than or equal to 5 micrometers.

Technical details of topologies, etching, etc., at the respective layers have not been detailed in the description above. However those skilled in the art shall appreciate that the layers, the areas, etc., in desirable shapes can be formed in a variety of technical means. Moreover those skilled in the art can further form the same structure in a devised implementation totally different from that described above. Moreover although the respective embodiments have been described above respectively, this will not suggest that measures in the respective embodiments can not be used in combination to advantage.

The embodiments of the invention have been described above. However these embodiments are merely intended to illustrate the invention but not to limit the scope thereof as defined by the appended claims and their equivalents. Those skilled in the art can make various substitutions and modifications to the invention without departing the scope thereof, and all these substitutions and modifications shall fall into the scope of the invention.

1. A semiconductor device, comprising:
a first area in which a plurality of device elements are stacked, wherein adjacent ones of the plurality of device elements are spaced by an interlayer insulation layer, and each of the device elements includes a corresponding gate conductor; and
a second area adjacent to the first area, wherein the interlayer insulation layer and the gate conductors extend from the first area to the second area, and there are electrically conductive vias in the second area through which the gate conductors and connected with wires,
wherein there are also support posts in the second area to support the interlayer insulation layer and the gate conductors.

2. The semiconductor device according to claim 1, wherein the plurality of device elements comprise common vertical channels.

3. The semiconductor device according to claim 2, wherein the plurality of device elements further comprise common core insulation layers surrounded by the vertical channels.

4. The semiconductor device according to claim 3, wherein the support posts comprise the vertical channels and the core insulation layers.

5. The semiconductor device according to claim 1, wherein the support posts are made of one of amorphous silicon and poly-silicon.

6. The semiconductor device according to claim 5, further comprising a semiconductor substrate, wherein the support posts are made of poly-silicon, and the bottoms of the support post belong to the same crystal domain as the semiconductor substrate.

7. The semiconductor device according to claim 1, wherein the distance between adjacent ones of the support posts is shorter than 100 times the thickness of the interlayer insulation layers.

8. The semiconductor device according to claim 7, wherein when the thickness of the interlayer insulation layers is smaller than 50 nanometers, the distance between adjacent ones of the support posts is smaller than or equal to 5 micrometers.

9. The semiconductor device according to claim 1, further comprising a semiconductor substrate into which the support posts are at least partially embedded.

10. The semiconductor device according to claim 1, wherein the plurality of device elements are stacked at a plurality of layers, the plurality of device elements at each of the layers are arranged in rows and columns, and the device elements in the same column comprise common gate conductors, whereas the gate conductors of adjacent columns of device elements are spaced by another insulation layer.

11. The semiconductor device according to claim 8, wherein in the second area, the gate conductors of the plurality of device elements are shaped stepwise, and the gate conductor at each of the layers is a level of step.

12. The semiconductor device according to claim 2, wherein the semiconductor device is an NAND memory, and at least some of the plurality of device elements form real strings of memory cells, whereas at least some others of the plurality of device elements form dummy strings of memory cells, and the support posts are dummy strings of memory cells.

13. A method for manufacturing a semiconductor device comprising a first area in which a plurality of device elements are stacked, and a second area in which there are electrically conductive vias for contact with the outside, the method comprising:
forming a stack of a plurality of scarification layers and a plurality of interlayer insulation layers alternately stacked;
forming openings through the respective layers in the stack of the layers;
forming vertical vias in openings in the first area;
forming support posts in openings in the second area;
removing the plurality of scarification layers so that the plurality of interlayer insulation layers float and are supported by the vertical vias and the support posts, and a part of the surfaces of the vertical vias are exposed;
forming an interlayer dielectric layer on the part of the surfaces of the vertical vias; and
forming gate conductors between adjacent ones of the interlayer insulation layers so that the gate conductors and the vertical vias are spaced by the interlayer dielectric layer.

14. The method according to claim 13, wherein the vertical vias are a conformal layer in the openings in the first area, and the method further comprises:
forming core insulation layers in the remaining spaces of the openings in the first area.

15. The method according to claim 13, wherein the support posts are formed at the same time as the vertical vias so that the support posts are made in the same structure and of the same material as the vertical vias.

16. The method according to claim 13, wherein the support posts are formed separately from the vertical vias and made in the same and/or different structures and of the same and/or different materials as the vertical vias.

17. The method according to claim 16, wherein the support posts are made of one of amorphous silicon and poly-silicon.

18. The method according to claim 13, wherein after the gate conductors are formed, the method further comprises:
etching for a plurality of times to expose downward the gate conductors at the respective layers in the contact area.

19. The method according to claim 18, wherein etching is performed each of the plurality of times to shield completely all the overlying gate conductors and to expose a part of the gate conductors at the immediately underlying layers.

20. The method according to claim 13, wherein the stack of the layers is formed on a semiconductor substrate and the openings extend into the semiconductor substrate.
